(19) United States
(12) Patent Application Publication
(10) Pub. No.: US 2016/0036449 A1
(43) Pub. Date: Feb. 4, 2016

(54) SIGNAL GENERATOR AND CONTROLLING METHOD THEREOF

(71) Applicant: Samsung Electro-Mechanics Co., Ltd., Suwon-si (KR)

(72) Inventor: Bon Young GU, Suwon-si (KR)

(73) Assignee: Samsung Electro-Mechanics Co., Ltd., Suwon-si (KR)

(21) Appl. No.: 14/733,558

(22) Filed: Jun. 8, 2015

(30) Foreign Application Priority Data
Jul. 31, 2014 (KR) 10-2014-0098424

(51) Int. Cl. H03L 1/00; H03L 7/06

(52) U.S. Cl. CPC H03L 1/00; H03L 7/06

(57) ABSTRACT

There is provided a signal generator including: a signal data transmitter selectively transmitting sample data obtained by sampling a reference signal at a predetermined frequency or a preset peak value, based on a variation section of the reference signal; and a signal outputter converting the sample data or the peak value transmitted from the signal data transmitter into an analog form and outputting an output signal having a target frequency.

### CROSS-REFERENCE TO RELATED APPLICATION

This application claims the benefit of Korean Patent Application No. 10-2014-0098424, filed on Jul. 31, 2014, entitled “Signal Generator and Controlling Method thereof′ which is hereby incorporated by reference in its entirety into this application.

### BACKGROUND

The present disclosure relates to a signal generator and a controlling method thereof.

In accordance with a rapid development of computers, information, and electronic communication industries, electronic communication devices that perform functions of wireless communications, electronic schedulers, and the like has also been gradually developed. The electronic communication devices include a key input unit to receive an operation signal such as characters, figures, a menu selection, and the like from a user. Here, as an example of the key input unit, a touch pad or a touchscreen that receives a signal using a plurality of configured key pads or touch pens has been mainly used.

Among these, since an input method using the touchscreen, which is a method of freely inputting the signal using a touch pen, or the like, which is an input means, is simpler than a key pad method that need to receive characters one by one through a large number of buttons, it has been well used. In the input method using the touchscreen described above, when a display device serving as the touchscreen and the input means are in contact with each other, whether or not the input is recognized may be notified to a user by an operation of a notification means such as sound, vibration, or the like.

Conventionally, a motor based vibration notification device has been used as the vibration notification means, it has a problem that response speed is slow. In order to solve the problem, a piezoelectric element converting electricity into displacement has been used.

### RELATED ART DOCUMENT

### Patent Document

(Patent Document 1) KR 2012-0096731

### SUMMARY

An aspect of the present disclosure may provide a signal generator for driving a piezoelectric actuator, or the like, that is able to solve a problem that a waveform of an output signal is distorted in the case in which a frequency region of the output signal of the signal generator is high.

A signal generator according to an exemplary embodiment may selectively transmit sample data obtained by sampling a reference signal at a predetermined frequency or a preset peak value, based on a variation section of the reference signal.

That is, the signal generator may transmit the preset peak value in a peak section of the reference signal and transmit the sample data in sections except for the peak section, so as to output an output signal having a predetermined target frequency. In addition, the preset peak value in the peak section and the sample data in other sections may be output at frequencies different from each other.

More specifically, a peak section detector may detect information on the peak section of the reference signal based on the sample data transmitted from the sample data outputter and control the data transmitter so as to transmit the peak value in the peak section of the reference signal and transmit the sample data in the sections except for the peak section.

The peak section detector 130 may transmit a select signal corresponding to the sample data to the data transmitter in the sections except for the peak section by using address information of the sample data transmitted from the sample data outputter 120 and transmit a select signal corresponding to the peak value in the peak section.

Therefore, in order to generate the output signal having the predetermined target frequency, the sample data or the peak value may be selectively applied and output according to whether or not the reference signal corresponds to the peak section. Here, the sample data may be transmitted to a signal outputter according to a frequency of a clock signal of a clock signal generator synchronized with the output frequency (sampling frequency).

Therefore, since an output of the sample data in the peak section is not ignored by outputting the preset peak value in the peak section of the reference signal and the sample data in other sections at output frequencies different from each other, distortion in a waveform of the output signal may be prevented in the case in which a frequency region of the output signal is high.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram showing a configuration of a signal generator according to an exemplary embodiment of the present disclosure;

FIG. 2 is a diagram showing a reference signal of the signal generator and a sampling of the reference signal according to an exemplary embodiment of the present disclosure;

FIG. 3 is a diagram showing an output signal using the signal generator according to an exemplary embodiment of the present disclosure; and

FIG. 4 is a flow chart showing a controlling method of a signal generator according to an exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

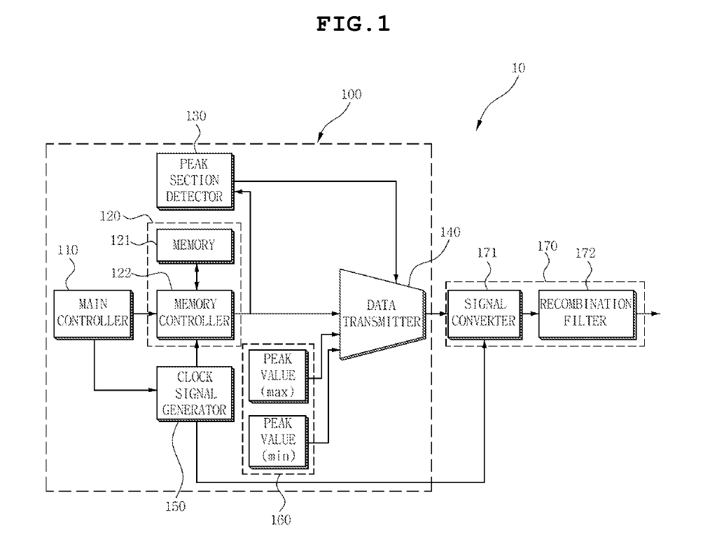

FIG. 1 is a block diagram showing a configuration of a signal generator according to an exemplary embodiment of the present disclosure. A signal generator according to an exemplary embodiment of the present disclosure includes a signal data transmitter 100 selectively transmitting sample data or a peak value of a reference signal and a signal outputter outputting an output signal having a target frequency.

The signal data transmitter 100 selectively transmits the sample data obtained by sampling the reference signal at a predetermined frequency or a preset peak value, based on a variation section of the reference signal. Here, the reference signal may be a sine wave pulse having the predetermined frequency.

In addition, the signal data transmitter 100 transmits the preset peak value in a peak section of the reference signal and transmits the sample data in sections except for the peak section.

In addition, the signal data transmitter 100 may include a sample data outputter 120, a data transmitter 140, a peak section detector 130, a clock signal generator 150, a peak value outputter 160, and a main controller 110. A description thereof will be provided below.

The sample data outputter 120 may store the sample data of the reference signal, output the sample data according to a predetermined output frequency, and include a memory 121 and a memory controller 122.

1) The memory 121 includes a look up table in which the sample data obtained by sampling the reference signal at the predetermined frequency is each stored in a preset address. 2) The memory controller 122 outputs the sample data at the predetermined frequency based on a control signal of the main controller 110 and transmits an address of the output sample data to the peak section detector 130.

That is, the memory controller 122 synchronizes a frequency for a clock signal of the clock signal generator 150 with the output frequency of the sample data and outputs the sample data of the look up table stored in the memory 121 depending on the clock signal.

Here, the output frequency of the sample data may be equal to an initial sampling frequency, but is not limited thereto. That is, the reference signal may be a sine wave pulse having the predetermined frequency and the reference signal may be sampled by a plurality of sample data according to a preset sampling frequency.

In addition, the sample data may form the look up table that is classified and stored according to a preset address and may be stored in the memory 121. For example, in the case in which the reference signal has a frequency of 7.81 Hz and is sampled at a sampling frequency of 8 kHz, the reference signal is sampled by 1024 sample data. In addition, the respective sample data forms the look up table that is classified and stored according to an address and is stored in the memory 121.

The data transmitter 140 may transmit the sample data or the peak value transmitted from the memory controller 122 to the signal outputter 170 and may be a multiplexer, but is not limited thereto.

In addition, the data transmitter may output the sample data transmitted from the memory controller 122 or a peak value input from the peak value outputter 160, according to the control signal of the peak section detector 130.

The peak section detector 130 detects information on a peak section of the reference signal based on the sample data transmitted from the sample data outputter 120 and controls output data of the data transmitter 140 according to the information of the peak section.

That is, the peak section detector 130 controls the data transmitter 140 so as to allow the peak value to be transmitted in the peak section of the reference signal and the sample data to be transmitted in sections except for the peak section.

More specifically, the peak section detector 130 transmits a select signal corresponding to the sample data to the data transmitter 140 in the section except for the peak section for the variation section of the reference signal, by using address information of the sample data transmitted from the sample data outputter 120.

In addition, in the case in which the peak section detector 130 detects a start point of the peak section by using the address information of the sample data, the peak section detector 130 transmits the select signal corresponding to the peak value to the data transmitter 140 so as to allow only the peak value to be transmitted to the signal converter 171 in the peak section.

The clock signal generator 150 generates a clock signal (square wave) having a predetermined frequency so as to be applied to the sample data outputter 120 and the signal outputter 170, and the frequency of the clock signal is controlled by the main controller 110 based on a target frequency of the output signal.

The peak value outputter 160 outputs a peak value of the reference signal according to the number of bits of the sample data to the data transmitter 140 and outputs a maximum peak value (Max) and a minimum peak value (Min). That is, in the case in which the number of bits of the sample data is 8 bits, the maximum peak value may be 255 and the minimum peak value may be 0. Here, the maximum peak value (Max) may be a source V_{dc} of the signal generator 10 and the minimum peak value (Min) may be a ground terminal Gnd.

The main controller 110 controls the output frequency of the sample data and the frequency of the clock signal based on the target frequency of the output signal, and the main controller controls the memory controller 122 so as to output the sample data at a frequency different from the preset peak value.

That is, in the case in which the target frequency of the output signal is higher than the frequency of the reference signal, the main controller 110 controls the frequency for the clock signal of the clock signal generator 150 so as to make the output frequency of the peak value in the peak section of the reference signal and the output frequency of the sample data in the sections except form the peak section different from each other.

More specifically, in the case in which the reference signal (8 Hz) is sampled by the sampling frequency of 8 kHz (the clock signal of the clock signal generator 150), the main controller 110 may increase the frequency of the clock signal of the clock signal generator 150 to 64 kHz in order to generate an output signal having the target frequency of 64 Hz.

In addition, the main controller 110 controls the memory controller 122 so as to allow an output of the sample data to be maintained at the same frequency as the sampling frequency (8 kHz). That is, in the case in which the clock signal of 64 kHz is applied to the memory controller 122 from the clock signal generator 150, the main controller 110 controls the memory controller 122 so as to allow the sample data corresponding to one address to be output every eighth, sixteenth, and so forth (8×n)-th clock signal CLK, whereby the output frequency of the sample data may be maintained at 8 kHz.

The signal outputter 170 converts the sample data or the peak value transmitted from the signal data transmitter 100 into an analog form so as to output the output signal having the target frequency, and includes a signal converter 171 and a recombination filter 172.

The signal converter 171 may convert the sample data or the peak value transmitted from the data transmitter 140 into the analog form and may be a digital-analog converter.

The recombination filter 172 may output the output signal by performing noise removal and averaging processes for the sample data or the peak value transmitted from the signal converter 171 and may be a low-pass filter.

That is, by the averaging process of the data (sample data or peak value) converted into the analog form by the signal converter 171, a final output signal of a sine wave shape is output.

Therefore, as described above, since the output of the sample data in the peak section is not ignored by outputting the preset peak value in the peak section of the reference signal and the sample data in other sections at output frequencies different from each other, distortion in a waveform of the output signal may be prevented in the case in which a frequency region of the output signal is high.

In addition, in generating the output signal having the target frequency higher than the frequency of the reference signal, a size of the look up table stored in the memory may be minimized and a process of generating the output signal may be simplified through a selective application of the output data according to the variation section of the reference signal.

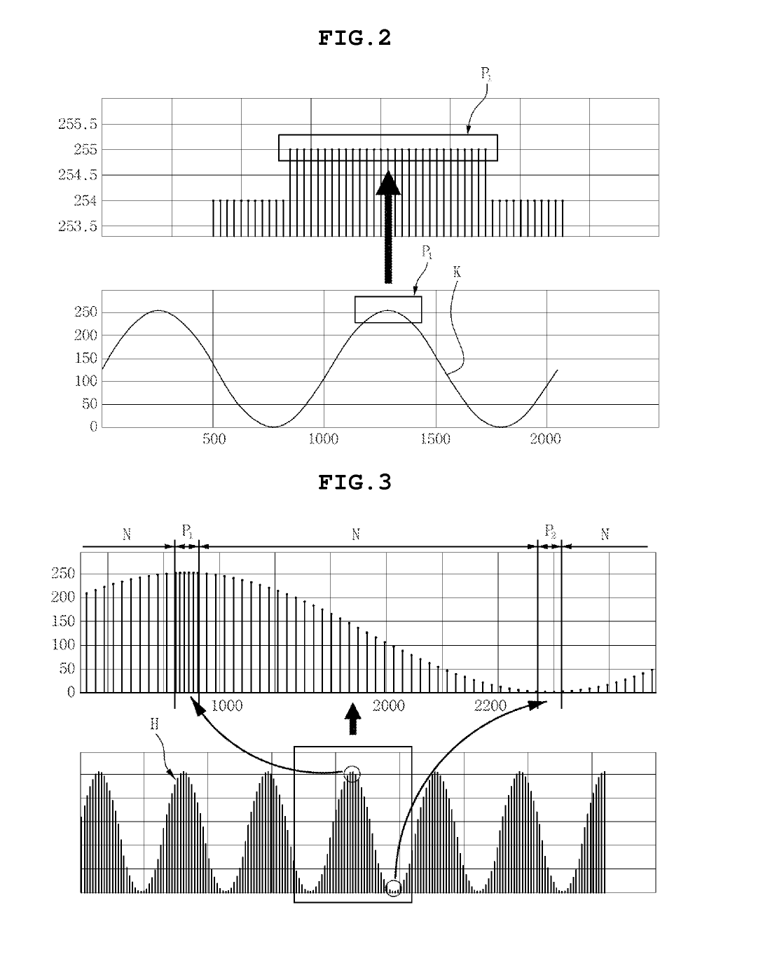

Hereinafter, the signal generator and the controlling method thereof according to an exemplary embodiment of the present disclosure will be described in more detail with reference to FIGS. 2 to 4.

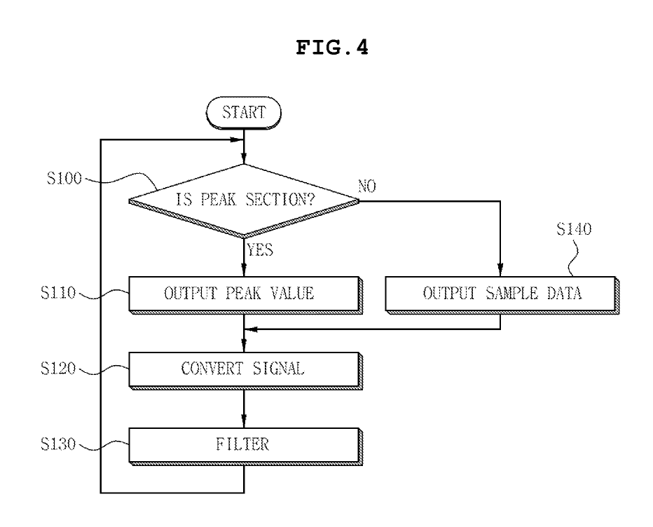

FIG. 2 is a diagram showing a reference signal of the signal generator and a sampling of the reference signal according to an exemplary embodiment of the present disclosure, FIG. 3 is a diagram showing an output signal using the signal generator according to an exemplary embodiment of the present disclosure, and FIG. 4 is a flow chart showing a controlling method of a signal generator according to an exemplary embodiment of the present disclosure.

As shown in FIG. 2, in the case in which a value corresponding to a peak section P₁ of a reference signal k (8 Hz) is sampled by a sample data of a digital format of 8 bits based on a predetermined sampling frequency (e.g., 8 kHz), a value of 255 (maximum peak value) is shown in the proximity of a peak in the peak section P₁.

In addition, in the case in which it is intended to output an output signal having a target frequency higher than the reference signal k (8 Hz), the main controller 110 controls the memory controller 122 so as to load and output an address of the sample data of the look up table of the memory 121 at a predetermined jump size.

That is, in the case in which the target frequency (16 Hz) of the output signal is two times higher than the reference signal k (8 Hz), the main controller 110 controls the memory controller 122 so as to load and output the sample data while increasing the address of the sample data by ‘2’ (the jump size=2).

However, in the case in which the target frequency of the output signal is higher than the frequency of the reference signal, the jump size for the look up table of the memory controller 122 is increased. Thereby, the sample data in the peak section is skipped, which may cause signal distortion in the peak section of the output signal.

Therefore, as shown in FIGS. 3 and 4, first, the peak section detector 130 determines whether or not the reference signal corresponds to a peak section (P₁ or P₂) based on address information of the sample data of the reference signal transmitted from the memory controller 122 (S100).

Nest, in the case in which the reference signal k corresponds to the peak section (P₁ or P₂), the peak section detector 130 transmits the select signal corresponding to a peak value (255 or 0) to the data transmitter 140 so as to output the peak value (255 or 0) (S110). Here, the peak value (255 or 0) is output depending on a frequency (e.g., 64 kHz) of the clock signal determined by the main controller 110 based on the target frequency of the output signal H.

In addition, in the case in which the reference signal k does not correspond to the peak section (P₁ or P₂), the peak section detector 130 transmits the select signal corresponding to the sample data to the data transmitter 140 so as to output the sample data (S140). Here, the main controller 110 controls the memory controller 122 so as to allow an output of the sample data to be maintained at the same frequency as the sampling frequency (8 kHz).

That is, in the case in which the clock signal of 64 kHz is applied to the memory controller 122 from the clock signal generator 150, the main controller 110 controls the memory controller 122 so as to allow the sample data corresponding to one address to be output every eighth CLK, whereby the output frequency of the sample data may be maintained at 8 kHz.

Therefore, as shown in FIG. 3, since output frequencies between the sample data or the peak values in the peak section (P₁ or P₂) of the reference signal k and the sections (N section) that do not correspond to the peak section (P₁ or P₂) of the reference signal are different, intervals between the sample data and the peak values are different from each other.

In addition, the signal converter 171 converts the sample data or the peak value transmitted from the data transmitter 140 into an analog form using a digital-analog converter (S120). Here, the digital-analog converter may be designed to have 8 bits, but is not limited thereto.

The recombination filter 172 may output the output signal H by performing noise removal and averaging processes for the sample data or the peak value transmitted from the signal converter 171 (S130). Here, the recombination filter 172 may be a low-pass filter and the output signal H may be a sine wave form, but are not limited thereto.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A signal generator comprising:
a signal data transmitter selectively transmitting sample data obtained by sampling a reference signal at a predetermined frequency or a preset peak value, based on a variation section of the reference signal; and
a signal outputter converting the sample data or the peak value transmitted from the signal data transmitter into an analog form and outputting an output signal having a target frequency.

2. The signal generator of claim 1, wherein the signal data transmitter transmits the preset peak value in a peak section of the reference signal and transmits the sample data in sections except for the peak section, and the preset peak value and the sample data are transmitted at frequencies different each other.

3. The signal generator of claim 2, wherein the signal data transmitter includes:
a sample data outputter storing the sample data and outputting the sample data according to a predetermined output frequency;
a data transmitter transmitting the sample data or the peak value to the signal outputter;
a peak section detector detecting information on the peak section of the reference signal based on the sample data transmitted from the sample data transmitter and controlling output data of the data transmitter according to the information on the peak section;
a clock signal generator generating a clock signal having a predetermined frequency so as to be applied to the sample data outputter and the signal outputter; and
a main controller controlling an output frequency of the sample data and a frequency of the clock signal based on the target frequency of the output signal.

4. The signal generator of claim 3, wherein the peak section detector controls the data transmitter so as to transmit the peak value in the peak section of the reference signal and transmit the sample data in sections except for the peak section.

5. The signal generator of claim 3, further comprising a peak value outputter outputting a peak value of the reference signal depending on the number of bits of the sample data to the data transmitter.

6. The signal generator of claim 4, wherein the sample data outputter includes:
a memory including a look up table in which the sample data obtained by sampling the reference signal at the predetermined frequency is stored according to a preset address; and
a memory controller outputting the sample data according to a frequency of the clock signal synchronized with the output signal and transmitting an address of the output sample data to the peak section detector, based on a control signal of the main controller.

7. The signal generator of claim 5, wherein the main controller controls the memory controller so as to allow the sample data to be output at a frequency different from the preset peak value.

8. The signal generator of claim 3, wherein the main controller controls a frequency of the clock signal of the clock signal generator based on the target frequency of the output signal.

9. The signal generator of claim 3, wherein the signal outputter includes:
a signal converter converting the sample data or the peak value transmitted from the data transmitter into the analog form; and
a recombination filter outputting the output signal through noise removal and averaging processes of the sample data or the peak value transmitted from the signal converter.

10. A controlling method of a signal generator, the controlling method comprising:
a data transmitting operation, by a signal data transmitter, selectively transmitting sample data obtained by sampling a reference signal at a predetermined frequency or a preset peak value, based on a variation section of the reference signal; and
an output signal generating operation, by a signal outputter, converting the sample data or the peak value transmitted from the signal data transmitter into an analog form and outputting an output signal having a target frequency.

11. The controlling method of claim 10, wherein the data transmitting operation includes:
outputting, by a sample data outputter, the sample data which is preset according to a predetermined output frequency;
detecting, by a peak section detector, information on the peak section of the reference signal based on the sample data transmitted from the sample data transmitter;
controlling, by the peak section detector, output data of the data transmitter according to the information on the peak section of the reference signal;
generating, by a clock signal generator, a clock signal having a predetermined frequency so as to be applied to the sample data outputter and the signal outputter; and
controlling, by a main controller, an output frequency of the sample data and a frequency of the clock signal based on the target frequency of the output signal.

12. The controlling method of claim 11, wherein the outputting of the sample data according to a predetermined output frequency includes:
synchronizing, by a memory controller, the frequency of the clock signal with the output frequency; and
outputting, by the memory controller, the sample data of a look up table stored in a memory according to the clock signal synchronized with the output frequency.

13. The controlling method of claim 11, wherein the controlling of the output data of the data transmitter includes:
transmitting the preset peak value in the peak section of the reference signal; and
transmitting the sample data in sections except for the peak section.

14. The controlling method of claim 11, wherein the output signal generating operation includes:
converting, by a signal converter, the sample data or the peak value transmitted from the data transmitter into an analog form; and
outputting, by a recombination filter, the output signal through noise removal and averaging processes of the sample data or the peak value transmitted from the signal converter.
